(19) United States
(12) Patent Application Publication
(10) Pub. No.: US 2008/0303172 A1
(43) Pub. Date: Dec. 11, 2008

(54) METHOD FOR STACKING SEMICONDUCTOR CHIPS AND SEMICONDUCTOR CHIP STACK PRODUCED BY THE METHOD

(76) Inventors: Michael Bauer, Nittendorf (DE); Alfred Haimerl, Sinzing (DE); Angela Kessler, Regensburg (DE); Joachim Mahler, Regensburg (DE)

Correspondence Address: SCHWEGMAN, LUNDBERG & WOESSNER / INFINEON, P.O. BOX 2938, MINNEAPOLIS, MN, 55402, US

(21) Appl. No.: 11/760,949

(22) Filed: Jun. 11, 2007

(51) Int. Cl. H01L 23/48; H01L 21/50

(52) U.S. Cl. 257/777; 438/109; 257/E23.01; 257/E21.505

(57) ABSTRACT

Apparatus for packaging two chips includes, in some embodiments, a first chip having at least one elevation and at least one cutout on a bottom thereof. It also includes a second chip having at least one elevation and at least one cutout on a top thereof. In some embodiments disclosed, the elevations and cutouts of the first chip and the second chip are configured to allow the elevations to be intermeshed with the cutouts when the chips are stacked with the bottom of the first chip engaging the top of the second chip.

### TECHNICAL FIELD

The subject matter disclosed relates generally to apparatus, systems and methods for packaging semiconductor circuits, including devices with multiple semiconductor circuit chips.

### BACKGROUND

US2002074637 relates to a flip-chip arrangement and also a method for producing the arrangement comprising an upper chip and comprising a lower chip, which in each case have a rear side and a front side electrically connected to the rear side, the upper chip being arranged on the rear side of the lower chip and being electrically connected to the lower chip by means of terminal connections (bumps). The cutouts remaining between the chips are filled with an elastic underfill material (“underfill”).

U.S. Pat. No. 6,777,786 likewise relates to a stack arrangement comprising two chips, which are arranged on both sides of a leadframe and are connected to the leadframe with the aid of bumps. The free spaces between the chips are provided with underfill in this case, too.

In a further stack arrangement, an upper chip is soldered by its front side onto the front side of the lower chip via terminal connections, such that there are electrical contacts between both chips. For this purpose, the upper chip is placed by its front side onto the front side of the lower chip and an electrical connection is produced in this position (face-to-face assembly).

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 shows a schematic cross section through two chips provided for stacking,

FIG. 2 shows a schematic cross section through a stack comprising two chips in accordance with FIG. 1,

FIG. 3 shows a schematic cross section through two chips provided for stacking in accordance with one embodiment of the invention,

FIG. 4 shows a schematic cross section through two chips provided for stacking in accordance with another embodiment of the invention, and

FIG. 5 shows a schematic cross section through two chips provided for stacking in accordance with a further embodiment of the invention.

### DETAILED DESCRIPTION

Existing connection technology for stacked circuit chips allows cutouts to remain open between the chips so that cavities are formed. The cavities have to be filled with an underfill material in a further process step in order to buffer mechanical stresses between the two chips. In the course of underfilling there is very often the risk of inadequate filling of the cavities between circuit dies or inadequate adhesion of the material to the die surfaces, which is undesirable

According to some embodiments of the invention, a semiconductor chip stack has a first chip and a second chip, which have a respective chip top side and a respective chip underside, the first chip having at least one elevation and at least one cutout on its chip underside, and the second chip having at least one elevation and at least one cutout on its chip top side. In this case, the chips are stacked in such a way that the at least one elevation of the first chip engages into the at least one cutout of the second chip and, conversely, the at least one elevation of the second chip engages into the at least one cutout of the first chip. The elevations and the cutouts are designed so as to enable the two chips to be joined together with an accurate fit wherein the second chip and the first chip are stacked such that the elevations are intermeshed with the cutouts so that the surfaces form a substantially continuous contact area.

Constructing the chips with intermeshed elevations and cutouts on opposing chip surfaces reduces or prevents formation of cavities between the chips. Those cavities would otherwise have to be filled by means of a further technologically complicated underfill process. Use of intermeshed elevations and cutouts allows elimination of the entire underfill process step.

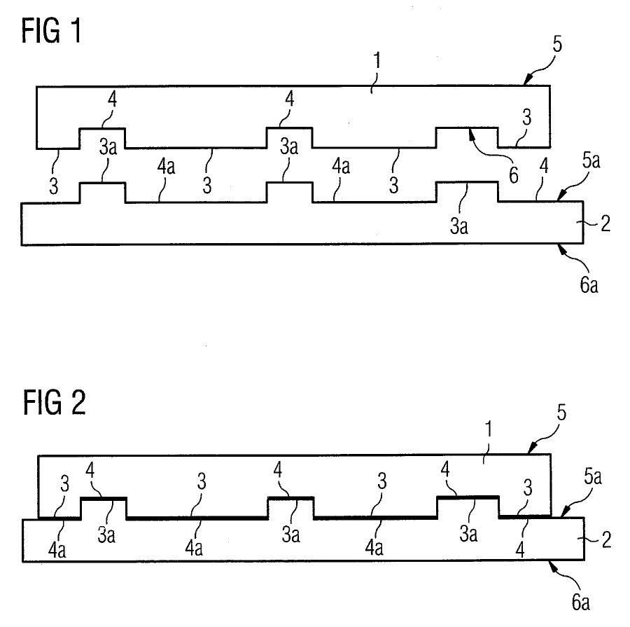

FIG. 1 shows a schematic cross section through two chips provided for stacking, which are represented as an integral structure in order to illustrate the inventive concept. The figure shows an upper chip 1 having a chip top side 5 and having a chip underside 6 and also a lower chip 2 having a chip top side 5a and a chip underside 6a.

On the sides 6, 5a facing one another, the two chips have elevations 3, 3a and cutouts 4, 4a, the elevations 3 on the chip underside 6 of the upper chip 1 being situated above the cutouts 4a on the chip top side 6a of the lower chip 2 and, conversely, the cutouts 4 on the underside 6 of the upper chip 1 being situated above the elevations 3a on the top side 6a of the lower chip 2, and lying opposite each elevation 3 on the chip underside 6 of the upper chip 1 there is a cutout 4a of approximately equal size on the chip top side 5a of the lower chip 2 and, conversely, lying opposite each cutout 4 on the chip underside 6 of the upper chip 1 there is a cutout 4a on the chip top side 5a of the lower chip 2, thereby enabling the two chips 1, 2 to be joined together with an accurate fit such that the elevations are intermeshed with the cutouts so that the surfaces form a substantially continuous contact area.

FIG. 2 shows a schematic cross section through a stack comprising two chips 1, 2 in accordance with FIG. 1 after the chips 1, 2 have been joined together with an accurate fit. In this case, the elevations 3, 3a and the cutouts 4, 4a on those sides of the chips 1, 2 which face one another are intermeshed in such a way that points of contact between the two chips 1, 2 form a continuous contact area, represented as a solid thick line in the figure. The representation illustrates that the two chips 1, 2 have been joined together with an accurate fit such that the elevations are intermeshed with the cutouts so that the surfaces form a substantially continuous contact area.

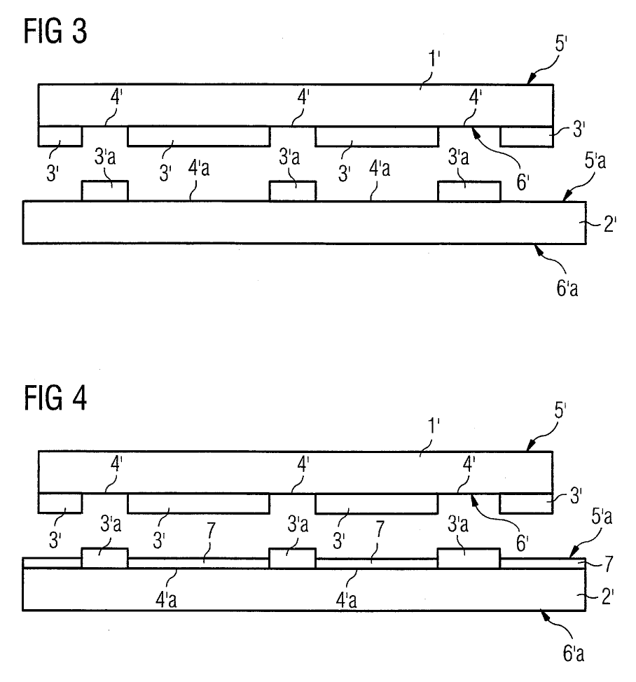

FIG. 3 shows a schematic cross section through two chips 1′, 2′ provided for stacking in accordance with one embodiment of the invention. The upper chip 1′ and the lower chip 2′ have a respective chip top side 5′, 5a′ and a respective chip underside 6′, 6a′. Elevations 3′ in the form of polymer layers are provided on the chip underside 6′ of the upper chip 1′. The upper chip 1′ additionally has cutouts 4′ formed by polymer-free spaces on the chip underside 6′.

The lower chip 2′ has elevations 3a′ on the chip top side 6a′, the elevations 3a′ being embodied as copper blocks. The free spaces between the elevations 3a′ form cutouts 4a′.

The elevations 3′ on the chip underside 6′ of the upper chip 1′ are situated above the cutouts 4a′ on the chip top side 6a of the lower chip 2′ and, conversely, the cutouts 4′ on the underside 6′ of the upper chip 1′ are situated above the elevations 3a′ on the top side 6a′ of the lower chip 2′, and lying opposite each elevation 3′ on the chip underside 6′ of the upper chip 1′ there is a cutout 4a′ of approximately equal size on the chip top side 5a′ of the lower chip 2′ and, conversely, lying opposite cutout 4′ on the chip underside 6′ of the upper chip 1′ there is a cutout 4a′ on the chip top side 5a′ of the lower chip 2′, thereby enabling the two chips 1′, 2′ to be joined together with their engaged surfaces intermeshed with an accurate fit to form a substantially continuous contact area.

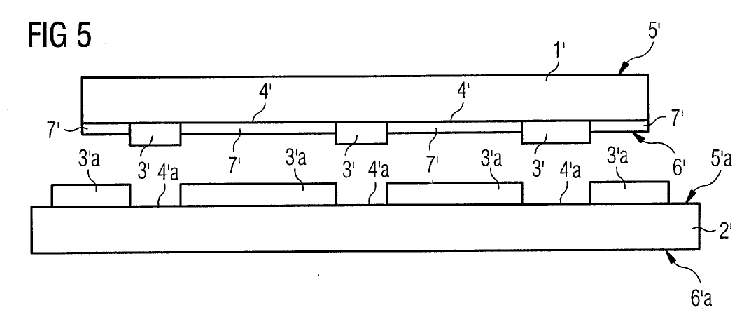

FIG. 4 shows a schematic cross-section through two chips 1′, 2′ provided for stacking in accordance with a further embodiment of the invention. The upper chip 1′ and the lower chip 2′ have a respective chip top side 5′, 5a′ and a respective chip underside 6′, 6a′.

Elevations 3′ in the form of polymer layers are provided on the chip underside 6′ of the upper chip 1′. The upper chip 1′ additionally has cutouts 4′ formed by polymer-free spaces on the chip underside 6′. A polymer layer is particularly well suited, on account of its deformability, to a joining together of the chips with an accurate fit. Moreover, in this case the insulating properties of polymers can be used for electrical insulation of specific regions.

In some embodiments of the invention, at least one elevation has a metal, for example by being embodied in the form of a copper block. A metallic structure may serve both for mechanical stabilization of the stack and for local electrical contact-connection between the two chips. The lower chip 2′ has elevations 3a′ on the chip top side 6a′, the elevations 3a′ being embodied as copper blocks. The free spaces between elevations 3a′ form cutouts 4a′, which are provided with an adhesive layer 7.

The elevations 3′ on the chip underside 6′ of the upper chip 1′ are situated above the cutouts 4a′ on the chip top side 6a of the lower chip 2′. Conversely, the cutouts 4′ on the underside 6′ of the upper chip 1′ are situated above the elevations 3a′ on the top side 6a′ of the lower chip 2′. Lying opposite each elevation 3′ on the chip underside 6′ of the upper chip 1′ there is a cutout 4a′ of approximately equal size on the chip top side 5a′ of the lower chip 2′, which cutout 4a′ is provided with the adhesive layer 7. Conversely, lying opposite each cutout 4′ on the chip underside 6′ of the upper chip 1′ there is a cutout 4a′ on the chip top side 5a′ of the lower chip 2′. Elevations 3′, 3a′, the cutouts 4′, 4a′ and the adhesive layer 7 are designed and dimensioned so as to enable the two chips 1′, 2′ to be joined together with an accurate fit such that the elevations are intermeshed with the cutouts thereby forming a substantially continuous contact area.

In some embodiments, at least one elevation on the chip underside of the first chip may be embodied as a polymer layer, while the at least one elevation on the chip top side of the second chip has metal. This construction is particularly simple to produce since the chips only have to be provided with one respective type of elevation per chip. Both a local targeted contact-connection and an accurate fit are made possible in this case.

In further embodiments of the invention, the at least one cutout has an adhesive layer. The adhesive layer provides improved mechanical adhesion between the chips and also for filling possible cavities between the chips.

The at least one cutout of the chips can be substantially filled by means of the joining together of the chips with an accurate fit. Thus, by way of example, it is possible reduce the proportionate volume of the cavities to less than 5% by vol. of the original volume of the at least one cutout. The difficulties caused by excessive cavities are thereby reduced.

FIG. 5 shows a schematic cross section through two chips 1′, 2′ provided for stacking in accordance with a further embodiment of the invention. The upper chip 1′ and the lower chip 2′ have a respective chip top side 5′, 5a′ and a respective chip underside 6′, 6a′. Elevations 3′ in the form of copper blocks are provided on the chip underside 6′ of the upper chip 1′. The free spaces between the elevations 3′ form cutouts 4′, which are provided with an adhesive layer 7′.

The lower chip 2′ has elevations 3a′ on the chip top side 6a′, which are embodied in the form of polymer layers. The free spaces between the elevations 3a′ form cutouts 4a′.

The elevations 3′ on the chip underside 6′ of the upper chip 1′ are situated above the cutouts 4a′ on the chip top side 6a of the lower chip 2′ and, conversely, the cutouts 4′ on the underside 6′ of the upper chip 1′ are situated above the elevations 3a′ on the top side 6a′ of the lower chip 2′, and lying opposite each elevation 3′ on the chip underside 6′ of the upper chip 1′ there is a cutout 4a′ of approximately equal size on the chip top side 5a′ of the lower chip 2′ and, conversely, lying opposite each cutout 4′ on the chip underside 6′ of the upper chip 1′ there is a cutout 4a′ provided with the adhesive layer 7′ on the chip top side 5a′ of the lower chip 2′, the elevations 3′, 3a′, the cutouts 4′, 4a′ and the adhesive layer 7′ being designed and dimensioned so as to enable the two chips 1′, 2′ to be joined together with an accurate fit such that the elevations are intermeshed with the cutouts so that the surfaces form a substantially continuous contact area.

The chips may have a respective chip front side with at least one integrated circuit and a respective chip rear side. In this case, those sides of the chips which face one another may be the chip front sides or chip rear sides. As an alternative, those sides of the chips which face one another may be the chip front side of the first chip and the chip rear side of the second chip.

In a further embodiment of the invention, the at least one cutout of a chip may have at least one electrical contact connected to at least one electrically conductive elevation of the second chip, such that an electrical contact arises between the integrated circuits on the chips.

Moreover, at least one chip may be provided with at least one passage contact that produces an electrical connection from the chip front side to the chip rear side. This option is particularly useful when pluralities of chips are stacked one on top of another.

In this case, the passage contact may be a so-called via or a contact hole embodied as a hole provided with a conductive material. A metal such as aluminum or tungsten may be used as via material for filling the holes.

In some embodiments, a method for stacking chips includes the following operations. A first process operation involves providing a first chip, which has a chip top side and a chip underside and also at least one elevation and at least one cutout on its chip underside.

A second process operation involves providing a second chip, which has a chip top side and a chip underside and also at least one elevation and at least one cutout on the chip top side.

In a further process operation, the chips are oriented in such a way that the at least one elevation on the chip underside of the first chip, said chip underside facing the second chip, is positioned above the at least one cutout on the chip top side of the second chip, said chip top side facing the first chip, and the at least one cutout on the chip underside of the first chip, said chip underside facing the second chip, is positioned above the at least one elevation on the chip top side of the second chip, said chip top side facing the first chip.

In a final process operation, the chips are joined together to form a stack, such that the elevations engage into the cutouts.

In embodiments discussed above a reliable connection between the chips can be realized. The elevations and the cutouts are intermeshed with an accurate fit, such that cavities formed between the chips are of substantially reduced volume so that the surfaces form a substantially continuous contact area.

In some of the embodiments discussed above, because the chip surfaces are structured with the elevations and cutouts intermeshed, it is possible to avoid a lateral displacement of the chips in the course of joining together said chips.

In some embodiments, the chips are situated in respective wafers before being joined together, such that they are joined together to form a wafer stack from which the chip stack is separated in a final singulation process operation. As a result, a plurality of semiconductor chip stacks can be created substantially simultaneously, which may lead to the increase in the production throughput.

Moreover, the at least one cutout on the first chip or on the second chip may be provided with an adhesive layer. As an alternative to this, cutouts on both chips may be provided with adhesive.

In some embodiments, before the chips are joined together, the at least one elevation has at least one surface part that is inclined with respect to the chip underside. The at least one elevation may have a wedge-shaped cross section. When the chips are joined together, the risk of possible air or gas inclusions between the chips can be reduced since the air or gases can easily escape laterally. On account of the deformability of the at least one elevation, the inclined surface can be flattened out again in the course of joining together the chips in such a way that it matches the cutout opposite it.

The above detailed description includes references to the accompanying drawings, which form a part of the detailed description. The drawings show, by way of illustration, specific embodiments in which the invention can be practiced. These embodiments are also referred to herein as “examples.” All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a “nonexclusive or”, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described embodiments (or one or more aspects thereof) may be used in combination. Other embodiments can be used, such as by one of ordinary skill in the art upon reviewing the above description. The Abstract is provided to comply with 37 C.F.R. §1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment. The scope of the invention should be determined with reference to the appended claims, along with the full scope of equivalents to which such claims are entitled.

We claim:

1. Apparatus, comprising
a first chip having at least one elevation and at least one cutout on a bottom thereof
a second chip having at least one elevation and at least one cutout on a top thereof, the elevations and cutouts of the first chip and the second chip configured to allow the elevations to be intermeshed with the cutouts when the chips are stacked with the bottom of the first chip above the top of the second chip.

2. The apparatus of claim 1, wherein the bottom of the first chip and the top of the bottom chip form a substantially continuous contact area.

3. The apparatus of claim 1, wherein at least one polymer elevation on the surface of one of the first and the second chips engages a metal surface of a cutout on the surface of the other of the first and second chips.

4. A semiconductor chip stack, comprising
a first chip having a respective chip top side, a respective chip underside, and having at least one elevation and at least one cutout on its underside, and
a second chip, having a respective chip top side and a respective chip underside, and having at least one elevation and at least one cutout on its chip top side, and wherein the second chip and the first chip are stacked such that the elevations are intermeshed with the cutouts to form a substantially continuous contact area.

5. The semiconductor chip stack according to claim 4, wherein at least one elevation is embodied in the form of a polymer layer.

6. The semiconductor chip stack according to claim 5, wherein in at least one elevation comprises metal.

7. The semiconductor chip stack according to claim 4, wherein the at least one elevation on the chip underside of the first chip includes a polymer layer and the at least one elevation on the chip top side of the second chip comprises metal.

8. The semiconductor chip stack according to claim 4, wherein at least one cutout has an adhesive layer.

9. The semiconductor chip stack according to claim 4, wherein the at least one elevation substantially fills the at least one cutout when the chips are joined together.

10. The semiconductor chip stack according to claim 4, wherein when the chips are stacked such that the elevations are intermeshed with the cutouts, so that the proportionate volume of the cavities formed between the chips is less than 5% by volume of the original volume of the at least one cutout.

11. The semiconductor chip stack according to claim 4, wherein one of the chips has a respective chip top side with at least one integrated circuit and a respective chip underside.

12. The semiconductor chip stack according to claim 11, wherein the at least one cutout of the first chip has at least one electrical contact connected to an at least electrically conductive elevation of the second chip, such that an electrical connection arises between electrical circuits on both chips.

13. The semiconductor chip stack according to claim 11, wherein the sides of the chips which face one another are the top sides.

14. The semiconductor chip stack according to claim 11, wherein least one of the chips has at least one passage contact for electrically connecting the chip top side to the chip underside.

15. A method for packaging chips, comprising:
providing a first chip having a chip top side and having a chip underside, which has at least one elevation and at least one cutout on the chip underside;
providing a second chip having a chip top side and having a chip underside, which has at least one elevation and at least one cutout on the chip top side;
orienting the chips such that the at least one elevation on the chip underside of the first chip, said chip underside facing the second chip, is positioned above the at least one cutout on the chip top side of the second chip, said chip top side facing the first chip, and the at least one cutout on the chip underside of the first chip, said chip underside facing the second chip, is positioned above the at least one elevation on the chip top side of the second chip, said chip top side facing the first chip; and
joining together the chips to form a semiconductor chip stack, such that the elevations intermesh with their respective cutouts on the surface of the adjacent chip.

16. The method according to claim 15, further comprising
Situating the chips in a respective wafer before joining them together, such that when they are joined together they form a wafer stack from which the chip stack is to be separated by singulation.

17. The method according to claim 15, wherein providing one of the first or the second chips also includes forming at least one elevation which is inclined with respect to the surface of chip underside.

18. The method according to claim 17 wherein providing one of the first or the second chips also includes forming at least one elevation which is inclined with respect to the surface of chip underside and the chip top and has a wedge-shaped cross-section.
